(19) United States
(12) Patent Application Publication
(10) Pub. No.: US 2026/0229459 A1
(43) Pub. Date: Aug. 6, 2026

(54) SYSTEMS AND METHODS FOR TUNING A FREQUENCY OF AN RF AMPLIFIER

(71) Applicant: Lam Research Corporation, Fremont, CA (US)

(72) Inventor: Amit Kumar Singh, Bengaluru (IN)

(21) Appl. No.: 19/159,143

(22) PCT Filed: Feb. 26, 2024
(86) PCT No.: PCT/US24/17362

§ 371 Date: Aug. 22, 2025

Related U.S. Application Data
(60) Provisional application No. 63/449,582, filed on Mar. 2, 2023.

(51) Int. Cl. H01J 37/32; H03F 3/195

(52) U.S. Cl. CPC H01J 37/32174; H01J 37/32128; H01J 37/32146; H01J 37/32935; H01J 2237/24564; H03F 3/195; H03F 2200/451

(57) ABSTRACT

Systems and methods for tuning a frequency of a radio frequency (RF) amplifier are described. One of the methods includes receiving a coil current measurement signal. The coil current measurement signal is measured at an input of an RF coil of a plasma chamber. The method further includes generating a normalized sawtooth signal based on the coil current measurement signal. The method includes applying a plurality of direct current (DC) references to the normalized sawtooth signal to determine a tuning frequency and controlling a frequency generator of a matchless plasma source according to the tuning frequency. The tuning frequency is the frequency of the RF amplifier. Furthermore, the method also includes a slow DC bus control to optimize RF amplifier efficiency.

### FIELD

The present embodiments relate to systems and methods for tuning a frequency of a radio frequency (RF) amplifier.

### BACKGROUND

The background description provided herein is for the purposes of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

In a plasma tool, a plasma source is provided. Also, a plasma chamber is provided and the plasma chamber is coupled to the plasma source. A substrate is placed inside the plasma chamber for processing. The plasma source generates a radio frequency (RF) signal and sends the RF signal to the plasma chamber for processing the substrate. However, the substrate is not processed in an efficient and desirable manner.

### SUMMARY

Embodiments of the disclosure provide systems, apparatus, methods and computer programs for tuning a frequency of a radio frequency (RF) amplifier. It should be appreciated that the present embodiments can be implemented in numerous ways, e.g., a process, an apparatus, a system, a device, or a method on a computer readable medium. Several embodiments are described below.

In some embodiments, it takes a long time to regulate power output from a plasma system. For example, in case of power control using a buck converter, a direct current (DC) bus voltage is charged. The DC bus voltage drops due to a load until a control system reacts. The control system reacts to the voltage drop and regulates the power output from the plasma system. In the example, a time period from a time the DC bus voltage is charged to a time the reaction by the control system is at least 20 microseconds (μs). The long amount of time to react is much greater than a predetermined rise time, such as 2.5 microseconds, of a transition of an amplification signal output from the RF amplifier.

In an embodiment, an agile DC rail is used to regulate and control RF power delivered to a plasma load. The agile DC rail includes an output of a DC-DC converter, e.g., the buck converter. Due to energy storage requirements at the agile DC rail, power control at the agile DC rail is not fast enough to drive a highly dynamic plasma impedance of the plasma load. Moreover, an additional fast frequency tuning loop is to be implemented to achieve zero voltage switching (ZVS) of switching devices of the RF amplifier. Two control loops, which include the control system for controlling the agile DC rail and the fast frequency tuning loop, are operated at different speeds to not interfere with each other. The operation at the different speeds limits power regulation and speed control. The buck converter is operated at a predetermined frequency, such as 200 kilohertz (kHz), to achieve the predetermined rise time. However, the operation at the predetermined frequency interacts with a frequency of operation of an analog frequency tuner of the plasma system.

In one embodiment, a frequency generator of a matchless plasma source is operated at a tuning frequency that is above a resonant frequency for a given dynamic load. Because the tuning frequency is restricted to be above the resonant frequency, the tuning frequency is varied to regulate power that is output from the RF amplifier. In the embodiment, the buck converter is not needed. When the buck converter is not used, it results in higher efficiency and greater power density. When the tuning frequency is achieved, zero voltage switching is achieved. As such, in the embodiment, a single control is provided for achieving the ZVS and for regulating the power.

Also, in an embodiment, a set frequency of the frequency generator is tuned to determine the tuning frequency in half of an RF time period. In this manner, frequency of the frequency generator is tuned very quickly to achieve zero voltage switching.

In one embodiment, a method of regulating a specified amount of plasma power by tuning a switching frequency, such as the tuning frequency, of the RF amplifier is described. While doing so, RF switching frequency range of the RF amplifier is limited to facilitate zero voltage switching for the switching devices of the RF amplifier. By using the switching frequency for both RF power regulation and zero voltage switching, the method potentially eliminates a front-end DC-DC converter stage, such as the buck converter, contributing to significant improvement in power conversion efficiency, power density, and reliability.

In an embodiment, the method, described herein, facilitates plasma power control by tuning an operating frequency of the RF amplifier. An antenna current is sensed, and based on zero detection of the antenna current, switching signals for the RF amplifier are generated. The switching frequency of the RF amplifier is limited to introduce a phase lag between switch voltage and current. The lagging switch current allows zero voltage switching for the each of the switching devices and contributes to efficiency improvement. Even though the methods, described herein, do not need the agile DC rail to control power output from the RF amplifier, a slow DC bus rail can be used to set a DC voltage for a specified amount of power in a feed forward way. The methods, described herein, extend an operating plasma impedance of the RF amplifier with improvement in system efficiency.

In an embodiment, the methods, described herein, provide a faster, more reliable approach to plasma power control by tuning the operating frequency of the RF amplifier while maintaining zero voltage switching. It also extends a range of the operating plasma impedance by using an optional feed forward DC bus voltage. The methods combine power control and fast frequency tuning into a single control and provides a simpler, faster, and more reliable plasma power control.

In one embodiment, the methods described herein, start with a preset frequency, such as a high frequency of operation of the RF amplifier, and then modifies, such as moves up, the preset frequency to the tuning frequency. The high frequency results in a low gain, providing a soft and safe start for the RF amplifier. Transitioning from the high frequency to the tuning frequency results in a soft switching condition for the RF amplifier. For pulsing, after a few cycles, information about the tuning frequency can be stored and can be used to have a much faster response in subsequent cycles of operation of the RF amplifier.

In an embodiment, an electric mode (E mode) and a magnetic mode (H mode) of plasma presents different types of impedances to the RF amplifier. The E mode presents a very high load, and once the plasma is ignited, it transitions to the H mode. For a fixed frequency operation of the RF amplifier, a specification indicating a high voltage gain during the E mode results in a below resonance operation during the H mode. An example of the below resonance operation is a frequency of operation of the RF amplifier below a resonant frequency of operation of the RF amplifier. The below resonance operation is a hard switching mode and can result in large switching transients and subsequently result in failure of the switching devices. The methods, described herein, actively track a change in impedance of the plasma and tunes the preset frequency to operate the RF amplifier above a resonance condition, such as above the resonant frequency of operation. The tracking is much faster than the E to H mode transition, resulting in a safer E to H mode transition.

In an embodiment, RF power pulsing is received as a specification. The RF power pulsing is limited when the agile DC rail is used due to charging and discharging of one or more bus capacitors of the buck converter and, consequently, changing delivered power. The methods, described herein, changes a gain of the RF amplifier by applying the tuning frequency and the application of the tuning frequency is much faster than control of the agile DC rail.

In one embodiment, upper and lower frequency limits of operation of the RF amplifier result in a safe operating range for the DC-DC converter.

In an embodiment, a variable frequency-based control of the RF amplifier can output higher reactive power from the RF amplifier when the RF amplifier is used to manage a high quality factor (Q) load. For the high Q load, an efficiency of the RF amplifier can be low, especially when operated at low power. A feed forward-based control controls the slow DC bus rail based on predefined plasma power, and the RF power amplifier is simultaneously tuned to operate with less reactive power.

In one embodiment, since a DC bus link is not used for closed-loop power control, the agile DC rails can be made much slower. Therefore, a DC bus capacitor of the DC-DC converter can be very large to provide high frequency attenuation and low input impedance to the RF amplifier. All of these result in a stable and reliable operation.

In an embodiment, different gain settings of the RF amplifier are used during the E and H modes of operation. For example, different tuning frequencies of the RF amplifier are used during the E mode than used during the H mode. During the E mode, a gain of the RF amplifier is set lower compared to the H mode, and by doing this, a response time and overshoot or undershoot in both the E and H modes are optimized.

In one embodiment, a method for tuning a frequency of an RF amplifier is described. The method includes receiving a coil current measurement signal. The coil current measurement signal is measured at an input of an RF coil of a plasma chamber. The method further includes generating a normalized sawtooth signal based on the coil current measurement signal. The method includes applying a plurality of DC references to the normalized sawtooth signal to determine a tuning frequency and controlling a frequency generator of a matchless plasma source according to the tuning frequency. The tuning frequency is the frequency of the RF amplifier.

In an embodiment, a controller for tuning a frequency of an RF amplifier is described. The controller includes a processor. The processor receives a coil current measurement signal. The coil current measurement signal is measured at an input of an RF coil of a plasma chamber. The processor generates a normalized sawtooth signal based on the coil current measurement signal. The processor applies a plurality of DC references to the normalized sawtooth signal to determine a tuning frequency. The processor controls a frequency generator of a matchless plasma source according to the tuning frequency. The controller includes a memory device coupled to the processor. The tuning frequency is the frequency of the RF amplifier.

In an embodiment, a system is described. The system includes a matchless plasma source. The matchless plasma source includes a frequency generator that generates a digital pulsed signal. The matchless plasma source also includes a gate driver coupled to the frequency generator. The gate driver receives the digital pulsed signal to output a plurality of gate driver signals. The matchless plasma source includes an RF amplifier coupled to the gate driver. The RF amplifier has an output. The RF amplifier receives the plurality of gate driver signals to provide an amplification waveform at the output of the RF amplifier. The system further includes a resonant circuit coupled to the RF amplifier. The resonant circuit receives the amplification waveform to output a sinusoidal signal. The system includes a plasma chamber having an RF coil. The RF coil has an input coupled to the resonant circuit to receive the sinusoidal signal. The system includes a controller coupled to the matchless plasma source. The controller receives a coil current measurement signal measured at the input of the RF coil. The controller generates a normalized sawtooth signal based on the coil current measurement signal. The controller applies a plurality of DC references to the normalized sawtooth signal to determine a tuning frequency. The controller controls the frequency generator according to the tuning frequency.

Other aspects will become apparent from the following detailed description, taken in conjunction with the accompanying drawings.

### BRIEF DESCRIPTION OF THE DRAWINGS

The embodiments may best be understood by reference to the following description taken in conjunction with the accompanying drawings.

FIG. 1 is a diagram of an embodiment of a system to illustrate a determination of a tuning frequency of a radio frequency (RF) amplifier.

FIG. 2A is an embodiment of a graph to illustrate a method for determining the tuning frequency.

FIG. 2B is an embodiment of a graph to illustrate the method for determining the tuning frequency.

FIG. 2C is an embodiment of a graph to illustrate the method for determining the tuning frequency.

FIG. 2D is an embodiment of a graph to illustrate a modification, such as an increase, in a range of the tuning frequency with an increase in a predetermined upper peak value and a decrease in a predetermined lower peak value.

FIG. 3A is a diagram of an embodiment of a processor to illustrate details of the processor.

FIG. 3B is a diagram of an embodiment of a system for modifying a duty cycle of a pulsed direct current (DC) signal to output a modified DC signal.

FIG. 4 is a diagram of an embodiment of a system to illustrate details of the RF amplifier and a manner in which a power sensor is coupled to an output of the RF amplifier.

FIG. 5A is an embodiment of a graph to illustrate a control of power that is delivered from a matchless plasma source to achieve a predetermined rise time and a predetermined fall time.

FIG. 5B is an embodiment of a graph to illustrate occurrences of transition of plasma formed within a plasma chamber from an electric mode (E) to a magnetic mode (H) and transition of the plasma from the H mode to the E mode.

FIG. 5C is an embodiment of a graph to illustrate a change in a DC reference with a change in a level of a coil current passing through an RF coil.

FIG. 6 is an embodiment of a graph to illustrate that for different loads, a frequency generator of the system of FIG. 1 is operated at different tuning frequencies to achieve the zero voltage switching (ZVS).

FIG. 7 is an embodiment of a graph to illustrate that by controlling the tuning frequency, the RF amplifier becomes less reactive and provides the same amount of gain of RF power.

### DETAILED DESCRIPTION

The following embodiments describe systems and methods for tuning a frequency of a radio frequency (RF) amplifier. It will be apparent that the present embodiments may be practiced without some or all of these specific details. In other instances, well known process operations have not been described in detail in order not to unnecessarily obscure the present embodiments.

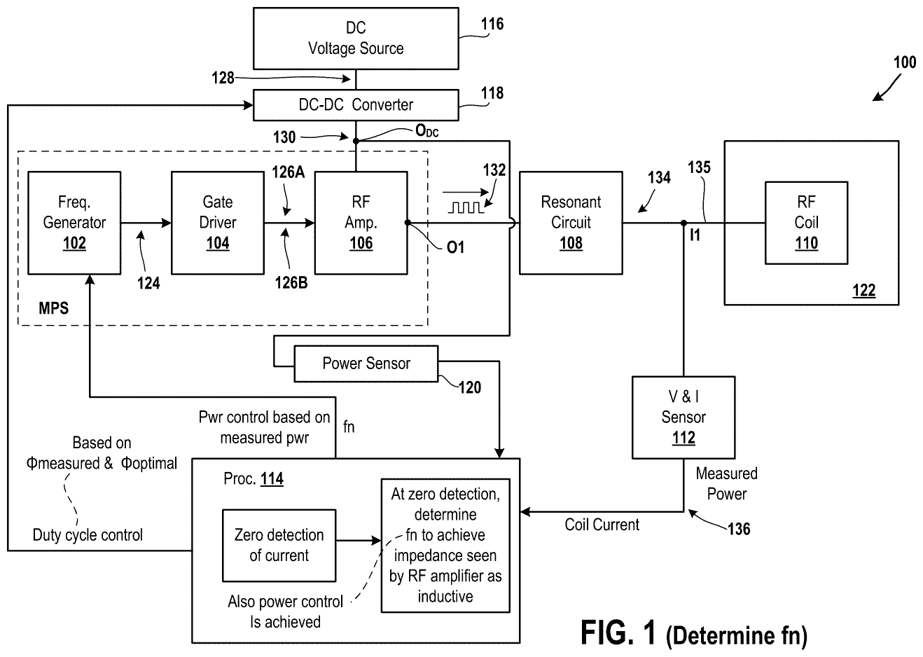

FIG. 1 is a diagram of an embodiment of a system 100 to illustrate a determination of a tuning frequency of the RF amplifier. The system 100 includes a frequency generator 102, a gate driver 104, an RF amplifier 106, a resonant circuit 108, an RF coil 110, a voltage and current (V & I) sensor 112, a processor 114, a direct current (DC) voltage source 116, a DC-to-DC (DC-DC) converter 118, a power sensor 120, and the plasma chamber 122. An example of the DC voltage source 116 is a battery or a capacitor. An example of the DC-to-DC converter 118 is an electronic circuit that converts voltage received from the DC voltage source 116 from one level to another. An example of the frequency generator 102 is a digital pulse signal generator, such as a clock source. As an example, the resonant circuit 108 includes one or more capacitors that are coupled to each other. As used herein, a processor is an application specific integrated circuit (ASIC), or a digital signal processor (DSP), or a programmable logic device (PLD), or a central processing unit (CPU), or a microprocessor, or a field programmable gate array (FPGA), or an integrated controller, or a microcontroller. The ASIC, the DSP, the PLD, the CPU, the microprocessor, the FPGA, the integrated controller, and the microcontroller are examples of an integrated circuit. The RF coil 110 is an example of an electrode of the plasma chamber 122. For example, the RF coil 110 is situated above a dielectric window of the plasma chamber 122. As another example, the RF coil 110 is a transformer coupled plasma (TCP) coil.

The frequency generator 102, the gate driver 104, and the RF amplifier 106 are components of a matchless plasma source (MPS). The matchless plasma source excludes an impedance matching circuit and a 50 ohm RF cable.

The processor 114 is coupled to the frequency generator 102, which is coupled to the gate driver 104. The gate driver 104 is coupled to the RF amplifier 106, which is coupled to the resonant circuit 108. The resonant circuit 108 is coupled to the RF coil 110. The processor 110 is also coupled to the DC-to-DC converter 118. The RF amplifier 106 is coupled to the DC-to-DC converter 118, which is coupled to the DC voltage source 116. The power sensor 120 is coupled to an output O_{DC} of the DC-to-DC converter 118. Also, an output O1 of the RF amplifier 106 is coupled to the resonant circuit 108. The power sensor 120 is coupled to the processor 114. The V & I sensor 112 is coupled between the RF coil 110 and the resonant circuit 108. For example, the V & I sensor 112 is coupled to an input Il of the RF coil 110 or an output of the resonant circuit 108 or between the input Il and the output of the resonant circuit 108. To illustrate, the V & I sensor 112 is coupled to an RF line 135, such as an RF communication medium or an RF conductor, which couples the resonant circuit 108 to the RF coil 110. In the illustration, the input Il is coupled to the RF line 135. The V & I sensor 112 is coupled to the processor 114.

The processor 114 provides a set frequency, such as a radio frequency, to the frequency generator 102. The frequency generator 102 generates a digital pulsed signal 124 having the set frequency, and provides the digital pulsed signal 124 to the gate driver 104. An example of a digital pulsed signal, as used herein, is a square waveform. The gate driver 104 generates two gate driver signals 126A and 126B based on the digital pulsed signal 124. For example, the gate driver 104 generates the gate driver signal 126A by allowing passage of the digital pulsed signal 124, and generates the gate driver signal 126B by inverting the digital pulse signal 124. The gate driver signal 126B is reversely synchronized with respect to the gate driver signal 126A. The gate driver 104 sends the gate driver signals 126A and 126B to the RF amplifier 106.

Also, the DC voltage source 116 generates a DC voltage signal 128 and supplies the DC voltage signal 128 the DC-to-DC converter 118. The DC-to-DC converter 118 converts the DC voltage signal 128 to output a DC voltage signal 130. For example, the DC-to-DC converter 118 changes a voltage level, such as an amount or an amplitude, of the DC voltage signal 128 to another voltage level of the DC voltage signal 130. To illustrate, the DC-to-DC converter 118 increases or decreases the voltage level of the DC voltage signal 128 to provide the DC voltage signal 130. The DC-to-DC converter 118 sends the DC voltage signal 130 to the RF amplifier 106.

Based on the DC voltage signal 130 and the gate driver signals 126A and 126B, the RF amplifier 106 generates an amplification waveform 132 at the output O1. For example, the gate driver signals 126A and 126B include the set frequency, which provides timings at which switches, such as transistors, of the RF amplifier 106 are turned on or off, and the DC voltage signal 130 includes an amplitude, such as a peak-to-peak voltage amplitude, of the amplification waveform 132. To further illustrate, the peak-to-peak amplitude of the amplification waveform 132 is provided by the voltage level of the DC voltage signal 128. In the further illustration, the amplification waveform 132 is a digital pulsed waveform and is not sinusoidal. It should be noted that each of the digital pulsed signal 124, the gate driver signal 126A, the gate driver signal 126B, and the amplification waveform 132 have the set frequency.

The amplification waveform 132 is sent from the output O1 to the resonant circuit 108. The resonant circuit 108 removes higher-order harmonics from the amplification waveform 132 to generate a sinusoidal waveform 134, and sends the sinusoidal waveform 134 to the RF coil 110. The sinusoidal waveform 134 has the set frequency.

A substrate, such as a semiconductor wafer, is placed on a substrate support, within the plasma chamber 122 for being processed. An example of the substrate support is an electrostatic chuck (ESC), which is coupled to a ground potential or to one or more matchless plasma sources or to one or more RF generators. When one or more process gases, such as an oxygen-containing gas or a nitrogen-containing gas or a chlorine-containing gas or a combination thereof, are supplied to an inside volume of the plasma chamber 122 in addition to the sinusoidal waveform 134, plasma is stricken or maintained within the plasma chamber 122 to process the substrate. Examples of processing the substrate include depositing a material on the substrate, or etching the substrate, or cleaning the substrate.

The V & I sensor 112 detects a coil current of the sinusoidal waveform to output a coil current measurement signal 136, and sends the coil current measurement signal 136 to the processor 114. The processor 114 receives the coil current measurement signal 136 from the processor 114 and processes the coil current measurement signal 136 to determine a tuning frequency fn. For example, the processor 114 identifies zero crossings of the coil current measurement signal 136, and one or more of the zero crossings and a DC reference are used by the processor 114 to determine the tuning frequency fn. The DC reference is described further below. The tuning frequency fn facilitates achieving a phase lag of an RF switch current passing through each of the switches of the RF amplifier 106 with respect to an RF switch voltage across the switch to achieve zero voltage switching (ZVS) of the switch.

The processor 114 provides the tuning frequency fn to the frequency generator 102 to modify the set frequency of the frequency generator 102 to the tuning frequency fn. The frequency generator 102 modifies the digital pulsed signal 124 based on the tuning frequency fn to output a modified digital pulsed signal. For example, the frequency generator 102 modifies, such as increases or decreases, the set frequency of the digital pulsed signal 124 to the tuning frequency fn to output the modified digital pulsed signal. As an example, the frequency generator 102 is operated at the set frequency for a predefined number of RF cycles, such as half of an RF cycle, or one RF cycle, or two RF cycles, or three RF cycles, of the digital pulsed signal 124 before the frequency generator 102 is operated at the tuning frequency fn. The gate driver 104 receives the modified digital pulsed signal and modifies the set frequency of each of the gate driver signals 126A and 126B to output modified gate driver signals, such as a first modified gate driver signal and a second modified gate driver signal, having the tuning frequency. The second modified gate driver signal is reversely synchronized compared to the first modified gate driver signal by the gate driver 104 in the same manner in which the gate driver signal 126B is reversely synchronized compared to the gate driver signal 126A.

The RF amplifier 106 receives the modified gate driver signals to modify the set frequency of the RF amplification signal 132 to the tuning frequency fn to output a modified amplification waveform. For example, the RF amplifier 106 generates the modified amplification waveform based on the modified gate driver signals in the same manner in which the amplification waveform 132 is generated based on the gate driver signals 126A and 126B. The modified amplification waveform having the tuning frequency fn is sent to the resonant circuit 108 to remove the higher-order harmonics from the modified amplification waveform to output a modified sinusoidal signal. The modified sinusoidal signal having the tuning frequency fn is sent to the RF coil 110 for processing the substrate.

In addition, power control is achieved based on the tuning frequency fn. For example, the V & I sensor 112 measures power of the sinusoidal signal 134 to generate values of measured power. The processor 114 receives the measured power and compares the measured power with set power of the digital pulsed signal 124. The processor 114 modifies the power of the digital pulsed signal 124 until the measured power is within a predetermined range from, such as equal to, the set power, to output the modified digital pulsed signal. The set power is provided by the processor 114 to the frequency generator 102. Upon receiving the set power, the frequency generator 102 generates the digital pulsed signal 124 at the set power.

Also, the processor 114 determines a measured phase φmeasured based on the DC reference and an optimal phase φoptimal. Further details of determining the measured phase and the optimal phase are provided below. The processor 114 controls a voltage level, such as an amplitude, of the DC voltage signal 130 based on the measured phase and the optimal phase. For example, the processor 114 controls, such as increases or decreases, the level the DC voltage signal 130 via a pulse width modulator (PWM), described below, until the measured phase is within a predetermined range from, such as equal to, the optimal phase. When the measured phase is within the predetermined range from optimal phase, the DC-to-DC converter 118 outputs a modified DC signal having a voltage level and sends the modified DC signal to the RF amplifier 106. The RF amplifier 106 generates the modified amplification waveform based on the modified DC signal in the same manner in which the RF amplifier 106 generates the amplification waveform 132 based on the DC voltage signal 130.

In one embodiment, the system 100 excludes the DC-to-DC converter 118. In the embodiment, the DC voltage source 116 is coupled directly to the RF amplifier 106.

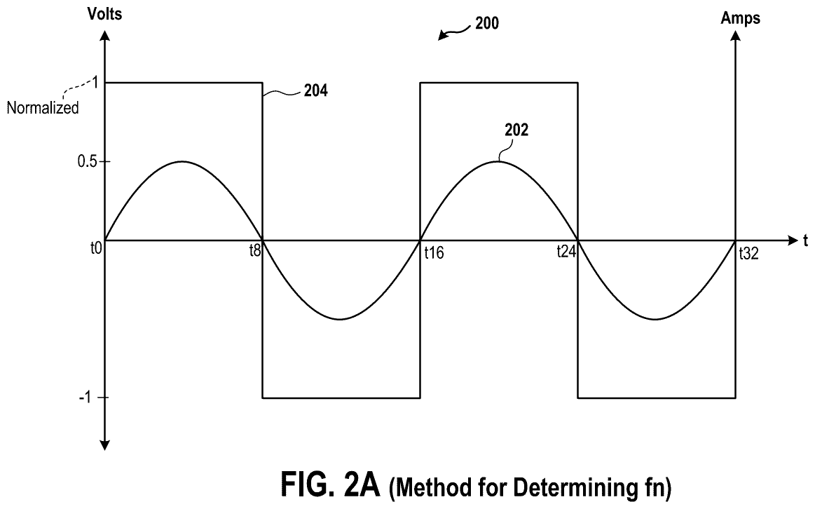

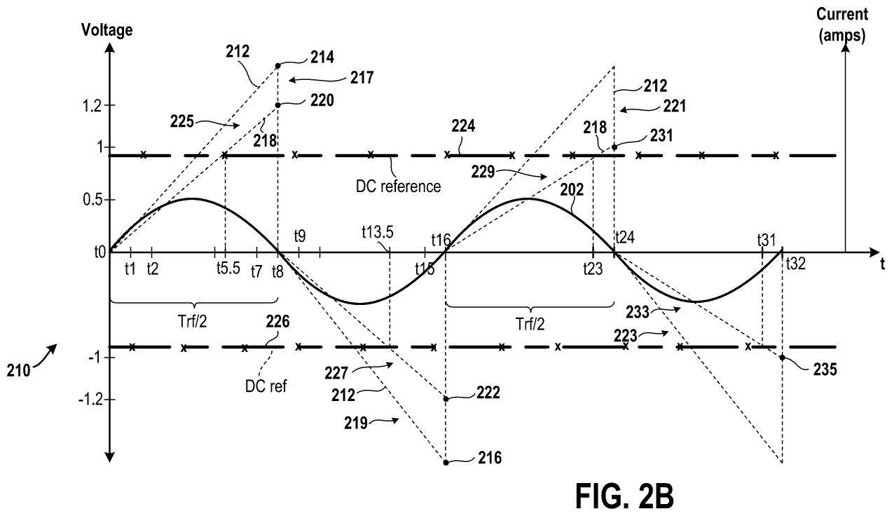

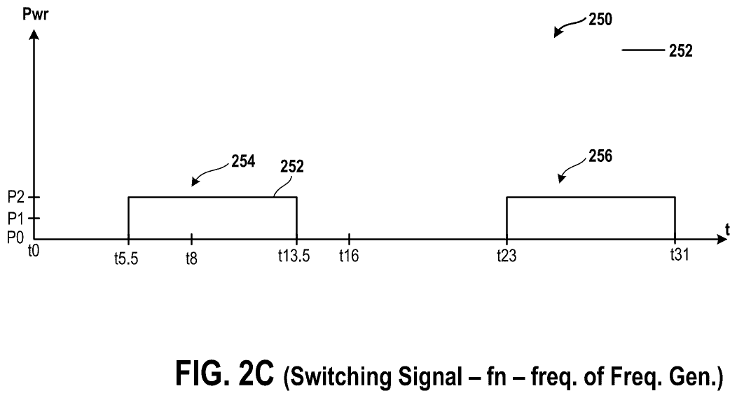

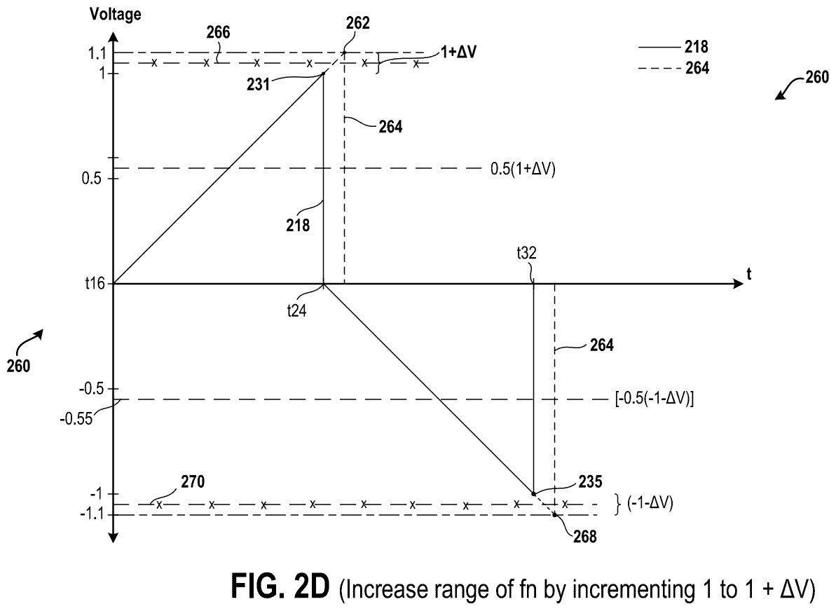

FIG. 2A is an embodiment of a graph 200 to illustrate a method for determining the tuning frequency fn. The graph 200 plots time t on an x-axis, current, in amperes (Amps) on a first y-axis, and voltage (Volts) on a second y-axis. The time t ranges from a time t0 to a time t32 in a progressively increasing manner. The graph 200 includes a coil current measurement signal 202, which is an example of the coil current measurement signal 136 (FIG. 1).

The processor 114 receives the coil current measurement signal 202 from the V & I sensor 112 (FIG. 1), and generates a square pulse 204 of a fixed magnitude, such as 1 volt or −1 volt, from the coil current measurement signal 202. For example, in an analog implementation of the processor 114, a comparator of the processor 114 compares each value of the coil current measurement signal 202 with zero to determine whether the value is greater than zero or less than zero. In the example, upon determining that the value of the coil current measurement signal 202 is greater than zero, the comparator outputs 1 volt as a value and upon determining that the value of the coil current measurement signal 202 is less than zero, the comparator outputs −1 volt as a value. In such a manner, in the example, the comparator outputs voltage values that transition between 1 volt and −1 volt periodically according to a period of the coil current measurement signal 202. Each transition of the voltage values occurs at a zero crossing of the coil current measurement signal 136. To illustrate, a first transition from 1 volt to −1 volt occurs at the time t8, a second transition from −1 volt to 1 volt occurs at the time t16, a third transition occurs from 1 volt to −1 volt at the time t24, and a fourth transition occurs from −1 volt to 1 volt at the time t32. In the illustration, the processor 114 determines that each of the zero crossings occurs at each of the times t0, t8, t16, and t32 at which a value of the coil current measurement signal 136 is zero. In this manner, the square pulse 204 extends from the time t0 to the time t32 and onwards to extend across a time period of occurrence of the coil current measurement signal 202. It should be noted that the time t8 occurs after the time t0, the time t16 occurs after the time t8, the time t24 occurs after the time t16, and the time t32 occurs after the time t24. As another example, functionality of the comparator that outputs the square pulse 204 is implemented using an FGPA instead of the comparator to provide a digital implementation of the processor 114.

FIG. 2B is an embodiment of a graph 210 to illustrate the method for determining the tuning frequency fn. The graph 210 plots the time t on an x-axis, current, in amperes (amps), on a first y-axis, and voltage on a second y-axis. The graph 210 includes a sawtooth signal 212 that is generated by the processor 114 (FIG. 1). The processor 114 integrates the square pulse 204 (FIG. 2A) to generate the sawtooth signal 212. For example, the processor 114 adds voltage values of the square pulse 204 over the time t to generate voltage values of the sawtooth signal 212. To illustrate, the processor 114 adds a first voltage value of the square pulse 204 at the time t1 with a second voltage value of the square pulse 204 at the time t2 and so on until an eighth voltage value of the square pulse 204 at the time t8 at which a zero crossing of the coil current measurement signal 202 occurs to generate a sawtooth pulse 217, having a peak voltage value 214, of the sawtooth signal 212. The sawtooth pulse 217 of the sawtooth signal 212 extends from the time t0 to the time t8. The peak voltage value 214 corresponds to the time t8. For example, the peak voltage value 214 occurs at the time t8. The processor 114 extends a line from a voltage value of zero to the peak voltage value 214 to generate the sawtooth signal 212. It should be noted that the peak voltage value 214 occurs at a time Trf/2, the which is half of a time Trf of a cycle of the coil current measurement signal 202. As another illustration, the processor 114 adds a first voltage value of the square pulse 204 at the time t8 with a second voltage value of the square pulse 204 at the time t9 and so on until an eighth voltage value of the square pulse 204 at the time t16 at which a zero crossing of the coil current measurement signal 202 occurs to generate a sawtooth pulse 219, having a peak voltage value 216, of the sawtooth signal 212. The sawtooth pulse 219 of the sawtooth signal 212 extends from the time t8 to the time t16. The peak voltage value 216 corresponds to the time t16. For example, the peak voltage value 216 occurs at the time t16. The processor 114 extends a line from a voltage value of zero at the time t8 to the peak voltage value 216 to generate the sawtooth signal 212.

It should be noted that the sawtooth pulses 217 and 219 are generated based on a first cycle of the coil current measurement signal 202. The first cycle occurs from the time t0 to the time t16. In a similar manner to that of generation of the sawtooth pulse 217, a sawtooth pulse 221 of the sawtooth signal 212 is generated by the processor 114 based on a second cycle of the coil current measurement signal 202. The second cycle occurs from the time t16 to the time t32. Also, in a manner similar to that of generation of the sawtooth pulse 219, a sawtooth pulse 223 of the sawtooth signal 212 is generated by the processor 114 based on the second cycle of the coil current measurement signal 202. The second cycle of the coil current measurement signal 202 is consecutive to the first cycle of the coil current measurement signal 202.

The processor 114 normalizes the sawtooth signal 212 to generate a normalized sawtooth signal 218, which is a voltage signal. For example, the processor 114 multiplies each value of the sawtooth pulse 217 by a predetermined constant to generate a normalized sawtooth pulse 225 of the normalized sawtooth signal 218 until an upper peak value 220, for the time t8, of the normalized sawtooth signal 218 is determined. In the example, the predetermined constant is received by the processor 114 from a user via an input device, which is coupled to the processor 114. Illustrations of the input device include a mouse, a keypad, a keyboard, a touch screen, and a stylus. In the example, the processor 114 resets the normalized sawtooth signal 218 at the time t8 to zero. To illustrate, the processor 114 transitions the normalized sawtooth signal 218 from the upper peak value 220 to a value of zero at the time t8. Also, in the example, the processor 114 multiplies each value of the sawtooth pulse 219 by the predetermined constant to generate a normalized sawtooth pulse 227 of the normalized sawtooth signal 218 until a lower peak value 222 of the normalized sawtooth signal 218 is determined. In the example, the processor 114 resets the lower peak value 222 at the time t16 to zero.

Continuing with the example, during the second cycle of the coil current measurement signal 202, the processor 114 multiplies each value of the sawtooth pulse 221 by the predetermined constant and divides the value by the peak value 220 to generate a normalized sawtooth pulse 229 of the normalized sawtooth signal 218 until an upper peak value 231 of the normalized sawtooth signal 218 is determined. The upper peak value 230 is determined based on the value of the sawtooth pulse 221 at the time t8. By dividing the sawtooth pulse 221 by the upper peak value 220 of the cycle 1 of the coil current measurement signal 202, the upper peak value 231 is closer to a preset value, such as 1 volt, compared to the upper peak value 220. To illustrate, the upper peak value 231 is 1 volt. In the example, the processor 114 resets the upper peak value 231 at the time t24 to zero. Also, in the example, the processor 114 multiplies each value of the sawtooth pulse 223 by the predetermined constant and divides the value by the lower peak value 222 to generate a normalized sawtooth pulse 233 of the normalized sawtooth signal 218 until a lower peak value 235 of the normalized sawtooth signal 218 is determined. By dividing the sawtooth pulse 223 by the lower peak value 222 of the cycle 1 of the coil current measurement signal 202, the lower peak value 235 is closer to a preset value, such as −1 volt, compared to the lower peak value 222. To illustrate, the lower peak value 235 is −1 volt. In the example, the processor 114 resets the lower peak value 235 at the time t32 to zero.

The processor 114 determines, based on an upper peak value, such as the upper peak value 220 or 231, of the normalized sawtooth signal 218, a DC reference 224. For example, the processor 114 limits the DC reference 224 to be between half of the upper peak value of the normalized sawtooth signal 218 and the upper peak value. To illustrate, the processor 114 limits the DC reference 224 to be between 0.5 volts and 1 volt. In the example, a value that is half of the upper peak value of the normalized sawtooth signal 218 is less than the upper peak value of the normalized sawtooth signal 218 by a predetermined increment, such as half, of the upper peak value 220 of the normalized sawtooth signal 218. In the example, the predetermined increment is received from the user via an input device. In the example, by limiting the DC reference 224 to be less than the upper peak value of the normalized sawtooth signal 218 and greater than half of the upper peak value of the normalized sawtooth signal 218, the tuning frequency fn above a resonant frequency of the RF amplifier 106 is achieved. Similarly, the processor 114 determines, based on a lower peak value, such as the lower peak value 222 or 235, of the normalized sawtooth signal 218, a DC reference 226. As an example, the processor 114 limits the DC reference 226 to be between half of the lower peak value of the normalized sawtooth signal 218 and the lower peak value of the normalized sawtooth signal 218. To illustrate, the processor 114 limits the DC reference 226 to be between −0.5 volts and −1 volt. In the example, a value that is half of the lower peak value of the normalized sawtooth signal 218 is greater than the lower peak value of the normalized sawtooth signal 218 by the predetermined increment, such as half, of the lower peak value of the normalized sawtooth signal 218. In the example, by limiting the DC reference 226 to be greater than the lower peak value of the normalized sawtooth signal 218 and less than half of the lower peak value of the normalized sawtooth signal 218, the tuning frequency fn above the resonant frequency of the RF amplifier 106 is achieved. In the example, the predetermined increment is received from the user via the input device.

It should be noted that when the DC reference 224 is equal to half of the upper peak value of the normalized sawtooth signal 218, zero real power is output from the RF amplifier 106 and when the DC reference 224 is equal to half of the upper peak value of the normalized sawtooth signal 218, a peak amount of real power is output from the RF amplifier 106. Similarly, when the DC reference 226 is equal to half of the lower peak value of the normalized sawtooth signal 218, zero real power is output from the RF amplifier 106 and when the DC reference 226 is equal to half of the lower peak value of the normalized sawtooth signal 218, a peak amount of real power is output from the RF amplifier 106.

FIG. 2C is an embodiment of a graph 250 illustrate the method for determining the tuning frequency fn. The graph 250 plots power of the modified digital pulsed signal to be output from the frequency generator 102 versus the time t. The power of the modified digital pulsed signal is plotted on a y-axis of the graph 250 and the time t is plotted on an x-axis of the graph 250. Power values, such as P0, P1, P2, and so on, of the power of the modified digital pulsed signal are plotted on the y-axis of the graph 250. The graph 250 plots a digital pulse signal 252 versus the time t.

After determining the DC references 224 and 226 (FIG. 2B), the processor 114 further determines based on one or more of the DC references 224 and 226, and the normalized sawtooth signal 218, the tuning frequency fn. For example, as an analog implementation of the processor 114, for the first cycle of the coil current measurement signal 202, a comparator of the processor 114 compares each value of the normalized sawtooth pulse 225 with the DC reference 224 to determine whether the value is greater than the DC reference 224 or less than the DC reference 224. Upon determining that the value of the normalized sawtooth pulse 225 is less than the DC reference 224, the comparator does not output a digital pulse 254 of the digital pulse signal 252 and upon determining that the value of the normalized sawtooth pulse 225 is greater than the DC reference 224, the comparator initiates outputting the digital pulse 254. To illustrate, from the time t0 to the time t5.5, the comparator determines that the value of the normalized sawtooth pulse 225 is less than the DC reference 224, and outputs the power value P0 of the digital pulse signal 252. In the illustration, at the time t5.5 at which the value of the normalized sawtooth pulse 225 transitions from being less than the DC reference 224 to being greater than the DC reference 224, the comparator transitions the digital pulse signal 252 from the power value of P0 to the power value P2 to initiate outputting the digital pulse 254. In the illustration, the comparator maintains the digital pulse 254 to be at the power value P2 during a time period, from the time t5.5 to the time t8 in which values of the normalized sawtooth pulse 225 are greater than the DC reference 224 until the normalized sawtooth pulse 225 resets. In the illustration, a portion of the normalized sawtooth signal 218 from the time t5.5 to the time t8 is above the DC reference 224.

Further, in the example, for the first cycle of the coil current measurement signal 202, the comparator of the processor 114 compares each value of the normalized sawtooth pulse 227 with the DC reference 226 to determine whether the value is greater than the DC reference 226 or less than the DC reference 226. Upon determining that the value of the normalized sawtooth pulse 227 is greater than the DC reference 226, the comparator continues to output the digital pulse 254 and upon determining that the value of the normalized sawtooth pulse 227 is less than the DC reference 226, the comparator stops outputting the digital pulse 254. In the illustration, the comparator continues to output the power value P2 of the digital pulse 254 until the normalized sawtooth pulse 227 transitions from being greater than the DC reference 226 to being less than the DC reference 226. In the illustration, at the time t16, the normalized sawtooth signal 218 resets and during a time period from the time t8 to the time t13.5, values of the normalized sawtooth pulse 227 are greater than the DC reference 226. In the illustration, at the time t8 and during the time period from the time t8 to the time t13.5, the comparator outputs the power value P2. In the illustration, the comparator determines that the normalized sawtooth pulse 227 transitions from being greater than the DC reference 226 to being less than the DC reference 226 at the time t13.5, and transitions the digital pulse signal 252 from the power value of P2 to the power value of P0 at the time t13.5 to stop outputting the digital pulse 254. In the illustration, the comparator outputs the digital pulse signal 252 to have the power value of P0 until the normalized sawtooth pulse 227 resets at the time t16. In such, a manner, the comparator generates the digital pulse 254 of the digital pulse signal 252.

Because the digital pulse 254 can be generated at the time Trf/2, which is the time t8, the tuning frequency fn is determined by the processor 114 in half of a time period of the radio frequency of the coil current measurement signal 202 (FIG. 2A). The determination of the tuning frequency fn in half of the time period of the radio frequency of the coil current measurement signal 202 is very fast frequency tuning of the frequency generator 102. As an illustration, the radio frequency of the coil current measurement signal 202 is equal to the radio frequency of the digital pulsed signal 124.

Further, in the example, for the second cycle of the coil current measurement signal 202, the comparator compares each value of the normalized sawtooth pulse 229 with the DC reference 224 to determine whether the value is greater than the DC reference 224 or less than the DC reference 224. Upon determining that the value of the normalized sawtooth pulse 229 is less than the DC reference 224, the comparator does not output a digital pulse 256 of the digital pulse signal 252 and upon determining that the value of the normalized sawtooth pulse 229 is greater than the DC reference 224, the comparator initiates outputting the digital pulse 256. To illustrate, from the time t16 to the time t23, the comparator determines that the value of the normalized sawtooth pulse 229 is less than the DC reference 224, and outputs the power value P0 of the digital pulse signal 252. In the illustration, at the time t23 at which the value of the normalized sawtooth pulse 229 transitions from being less than the DC reference 224 to being greater than the DC reference 224, the comparator transitions the digital pulse signal 252 from the power value of P0 to the power value P2 to initiate outputting the digital pulse 256. In the illustration, the comparator maintains the digital pulse 256 to be at the power value P2 during a time period, from the time t23 to the time t24 in which values of the normalized sawtooth pulse 229 are greater than the DC reference 224 until the normalized sawtooth pulse 229 resets. In the illustration, a portion of the normalized sawtooth signal 218 from the time t23 to the time t24 is above the DC reference 224.

Further, in the example, for the second cycle of the coil current measurement signal 202, the comparator of the processor 114 compares each value of the normalized sawtooth pulse 233 with the DC reference 226 to determine whether the value is greater than the DC reference 226 or less than the DC reference 226. Upon determining that the value of the normalized sawtooth pulse 233 is greater than the DC reference 226, the comparator continues to output the digital pulse 256 and upon determining that the value of the normalized sawtooth pulse 233 is less than the DC reference 226, the comparator stops outputting the digital pulse 256. In the illustration, the comparator continues to output the power value P2 of the digital pulse 256 until the normalized sawtooth pulse 233 transitions from being greater than the DC reference 226 to being less than the DC reference 226. In the illustration, at the time t32, the normalized sawtooth signal 218 resets and during a time period from the time t24 to the time t31, values of the normalized sawtooth pulse 233 are greater than the DC reference 226. In the illustration, at the time t24 and during the time period from the time t24 to the time t31, the comparator outputs the power value P2. In the illustration, at the time t31, the comparator determines that the normalized sawtooth pulse 233 transitions from being greater than the DC reference 226 to being less than the DC reference 226, stops outputting the digital pulse 256, and transitions the digital pulse signal 252 from the power value of P2 to the power value of P0 to stop outputting the digital pulse 256. In the illustration, the comparator outputs the digital pulse signal 252 to have the power value of P0 until the normalized sawtooth pulse 227 resets at the time t32. In such a manner, the comparator generates the digital pulse 256 of the digital pulse signal 252. As another example, functionality of the comparator that outputs the digital pulse signal 252 is implemented using an FGPA instead of the comparator to provide a digital implementation of the processor 114.

The digital pulse signal 252 is sometimes referred to herein as a switching signal for switching each of the switches of the RF amplifier 106 (FIG. 1). For example, the tuning frequency fn is a frequency with which each of the switches of the RF amplifier 106 (FIG. 1), operates, such as transitions, between an on state and an off state. To illustrate, the tuning frequency fn provides times of turning on and turning off of each of the switches of the RF amplifier 106. To further illustrate, the tuning frequency fn is a frequency at which a first one of the transistors of the RF amplifier 106 turns on and off, and a second one of the transistors of the RF amplifier 106 turns off and on. In the further illustration, the first one of the transistors is turned on at the time t5.5 and the second one of the transistors is turned off at the time t5.5. Also, in the further illustration, the first one of the transistors is turned off at the time t13.5 and the second one of the transistors is turned on at the time t13.5. Further, in the further illustration, the first one of the transistors is turned on at the time t23 and the second one of the transistors is turned off at the time t23. Also, the first one of the transistors is turned off at the time t31 and the second one of the transistors is turned on at the time t31.

FIG. 2D is an embodiment of a graph 260 to illustrate a modification, such as an increase, in a range of the tuning frequency fn with an increase in the upper peak value 231 and a decrease in the lower peak value 235 of the normalized sawtooth signal 218. The modification in the range of the tuning frequency fn facilitates processing the substrate using one or more different processes, such as using one or more different impedance values of plasma, compared to one more processes achieved using a range of the tuning frequency fn without the modification. The graph 260 plots voltage on a y-axis and the time t on an x-axis.

The processor 114 (FIG. 1) increases the upper peak value 231 of the normalized sawtooth signal 218 from 1 volt by an incremental value ΔV to a value of 1+ΔV to form another upper peak value 262 of a normalized sawtooth signal 264. Instead of generating the DC reference 224 (FIG. 2B) to be between the upper peak value 231 of the normalized sawtooth signal 218 and half of the upper peak value 231 of the normalized sawtooth signal 218, the processor 114 generates another DC reference 266 between the upper peak value 262 and half of the upper peak value 262. A value of half of the upper peak value 262 is represented as 0.5(1+ΔV). It should be noted that half is an example of the predetermined increment. The processor 114 uses the DC reference 266 and the normalized sawtooth signal 264 to determine another tuning frequency fn1 in the same manner in which the processor 114 uses the DC reference 224 and the normalized sawtooth signal 218 (FIG. 2B) to determine the tuning frequency fn. By using the upper peak value 262 instead of the upper peak value 231 of the normalized sawtooth signal 218, the range of the tuning frequency fn is modified.

Moreover, the processor 114 decreases the lower peak value 235 of the normalized sawtooth signal 218 (FIG. 2B) from −1 volt by the incremental value ΔV to a value of (−1−ΔV) to form another lower peak value 268 of the normalized sawtooth signal 264. Instead of generating the DC reference 226 (FIG. 2B) to be between the lower peak value 235 of the normalized sawtooth signal 218 and half of the lower peak value 235 of the normalized sawtooth signal 218, the processor 114 generates another DC reference 270 between the lower peak value 268 and half of the lower peak value 268. A value of half of the lower peak value 268 is represented as 0.5(−1−ΔV). It should be noted that half is an example of the predetermined increment. The processor 114 uses the DC reference 270 and the normalized sawtooth signal 264 to determine the other tuning frequency fn1 in the same manner in which the processor 114 uses the DC reference 226 and the normalized sawtooth signal 218 to determine the tuning frequency fn. By using the lower peak value 268 instead of the lower peak value 235 of the normalized sawtooth signal 218, the range of the tuning frequency fn is modified.

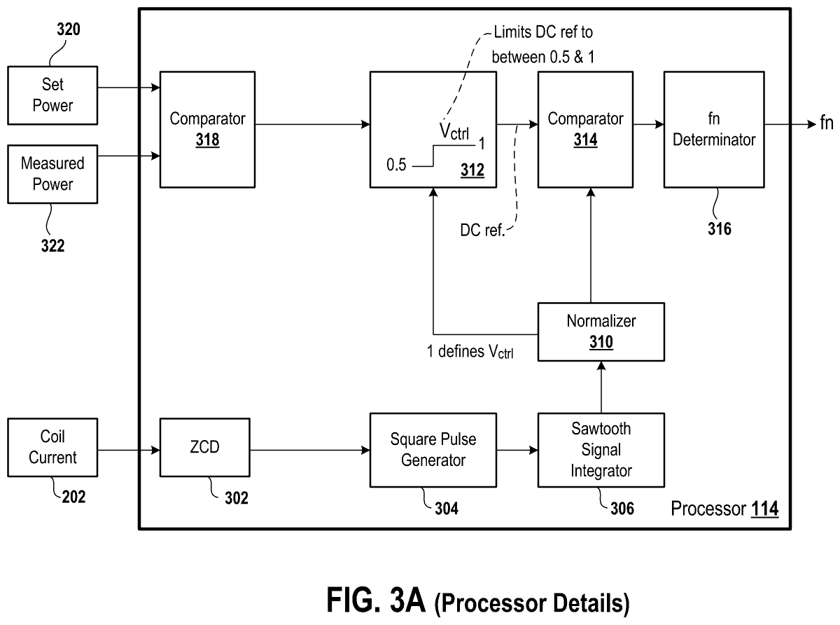

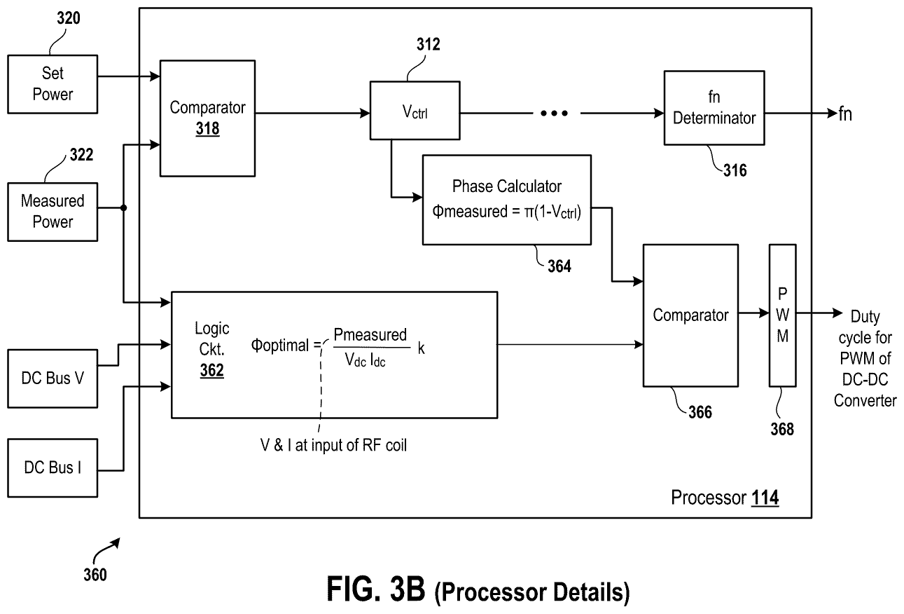

FIG. 3A is a diagram of an embodiment of the processor 114 to illustrate details of the processor 114. The processor 114 includes a zero current detector (ZCD) 302, a square pulse generator 304, a sawtooth signal integrator 306, a normalizer 310, a voltage controller 312, a comparator 314, a tuning frequency determinator 316, and a comparator 318. As an example, each of the ZCD 302, the square pulse generator 304, the sawtooth signal integrator 306, the normalizer 310, the voltage controller 312, the comparator 314, the tuning frequency determinator 316, and the comparator 318 is implemented as an integrated circuit. To illustrate, the ZCD 302 is a first integrated circuit and the square pulse generator 304 is a second integrated circuit. As another example, each of the ZCD 302, the square pulse generator 304, the sawtooth signal integrator 306, the normalizer 310, the voltage controller 312, the comparator 314, the tuning frequency determinator 316, and the comparator 318 is implemented as a computer software program that is executed by the processor 114 or a portion of a computer software program that is executed by the processor 114. To illustrate, the ZCD 302 is a portion of a computer software program and the square pulse generator 304 is another portion of the computer software program.

The ZCD 302 is coupled to the square pulse generator 304, which is coupled to the sawtooth signal integrator 306. The sawtooth signal integrator 306 is coupled to the normalizer 310. The normalizer 310 is coupled to the voltage controller 312 and the comparator 314. Also, each comparator 314 and 318 is coupled to the voltage controller 312.

The ZCD 302 receives the coil current measurement signal 202 (FIG. 2A) from the V & I sensor 112 (FIG. 1), and determines zero current crossings of the coil current measurement signal 202. For example, the ZCD 302 identifies times, such as the times t0, t8, and t16, at which values of the coil current measurement signal 202 are zero. To illustrate, the ZCD 302 receives the times t0, t8, and t16 from a timer of the V & I sensor 112 112 and also a correspondence between each of the times t0, t8, and t16 and the value of zero of the coil current measurement signal 202 from the V & I sensor 112. In the illustration, the ZCD 302 identifies from the correspondence that the values of the coil current measurement signal 202 at the times t0, t8, and t16 are zero, and determines that a zero current crossing of the coil current measurement signal 202 occurs at each of the times t0, t8, and t16. As another illustration, the processor 114 includes a timer, and the timer measures the times t0, t8, and t16 at which values of zero of the coil current measurement signal 202 are received by the processor 114 from the V & I sensor 112. In the illustration, the processor 114 determines that a zero current crossing of the coil current measurement signal 202 occurs at each of the times t0, t8, and t16.

The ZCD 302 provides the zero current crossings, such as the times t0, t8, and t16 and the value of zero, of the coil current measurement signal 202 to the square pulse generator 304. The square pulse generator 304 generates the square pulse 204 of the fixed magnitude based on the zero crossings of the coil current measurement signal 202. For example, the square pulse generator 304 transitions the square pulse 204 from a magnitude of −1 volt to a magnitude of 1 volt at the time t0 at which a zero crossing of the coil current measurement signal 202 occurs. To illustrate, the square pulse generator 304 includes the comparator, described above, that determines that values of the coil current measurement signal 202 are transitioning from a negative value to a positive value at the time to, and upon determining so, transitions the square pulse 204 from −1 volt to 1 volt at the time t0. Further, in the example, the square pulse generator 304 transitions the square pulse 204 from the magnitude of 1 volt to the magnitude of −1 volt at the time t8 at which a zero crossing of the coil current measurement signal 202 occurs. To illustrate, the comparator of the square pulse generator 304 determines that values of the coil current measurement signal 202 are transitioning from a positive value to a negative value at the time t8, and upon determining so, transitions the square pulse 204 from 1 volt to −1 volt at the time t8. It should be noted that functionality of the square pulse generator 304 is the same as the functionality of the comparator or the FPGA described above with reference to FIG. 2A.

The sawtooth signal integrator 306 integrates the square pulse 204 over the time t based on the zero crossings of the coil current measurement signal 202 to generate the sawtooth signal 212 (FIG. 2B). Examples of how the sawtooth signal 212 is generated based on the zero crossings are provided above. To illustrate, the sawtooth signal integrator 306 adds values of the square pulse 204 from the time t0 to the time t8 to generate the sawtooth pulse 217 (FIG. 2B) having the peak value 214 (FIG. 2B) and adds values of the square pulse 204 from the time t8 to the time t16 to generate the sawtooth pulse 219 (FIG. 2B) having the peak value 216 (FIG. 216). Also, the sawtooth signal integrator 306 generates the sawtooth pulses 221 and 223 of the sawtooth signal 212 in the same manner as that described above with reference to FIG. 2B.

The sawtooth signal integrator 306 provides the sawtooth signal 212 to the normalizer 310. The normalizer 310 normalizes the sawtooth signal 212 to output the normalized sawtooth signal 218 (FIG. 2B). For example, the normalizer 310 generates the normalized sawtooth signal 218 from the sawtooth signal 212 in the same manner as that described above with reference to FIG. 2B.

The normalizer 310 provides the normalized sawtooth signal 218 to the voltage controller 312 and to the comparator 314. The voltage controller 312 determines a first set of upper and lower limits from the upper peak value of the normalized sawtooth signal 218, a second set of upper and lower limits from the lower peak value of the normalized sawtooth signal 218, the DC reference 224 based on the upper and lower limits of the first set, and the DC reference 226 based on the upper and lower limits of the second set. For example, the voltage controller 312 calculates the upper limit of the first set to be the upper peak value of the normalized sawtooth signal 218, and calculates the lower limit of the first set to be such that a difference between the upper limit of the first set and the lower limit of the first set is equal to the predetermined increment. To illustrate, the voltage controller 312 calculates the lower limit of the first set to be half of the upper peak value of the normalized sawtooth signal 218. Continuing with the example, the voltage controller 312 generates the DC reference 224 (FIG. 2B) to be between the upper limit of the first set and the lower limit of the first set.

In the example, the voltage controller 312 calculates the upper limit of the second set to be the lower peak value of the normalized sawtooth signal 218 (FIG. 2B), and calculates the lower limit of the second set to be such that a difference between the upper limit of the second set and the lower limit of the second set is equal to the predetermined increment. To illustrate, the voltage controller 312 calculates the lower limit of the second set to be half of the lower peak value of the normalized sawtooth signal 218. Continuing with the example, the voltage controller 312 generates the DC reference 226 to be between the upper limit of the second set and the lower limit of the second set. The voltage controller 312 provides the DC references 224 and 226 to the comparator 314.

The comparator 314 compares voltage values of the normalized sawtooth signal 218 with the DC references 224 and 226 to output the digital pulse signal 252 (FIG. 2C). Examples of functionality of the comparator 314 to generate the digital pulse signal 252 are provided above. The comparator 314 provides the digital pulse signal 252 to the frequency determinator 316.

The frequency determinator 316 determines the tuning frequency fn based on the digital pulse signal 252 and outputs the tuning frequency fn. Examples of determination of the tuning frequency fn from the digital pulse signal 252 are provided above with reference to FIG. 2C.

The comparator 318 receives set power 320, which is described above, from the user via the input device. Also, the comparator 318 receives measured power 322 from the V & I sensor 112 of FIG. 1. The V & I sensor 112 outputs the measured power 322 by multiplying voltage and current of the sinusoidal signal 134 (FIG. 1). For example, the V & I sensor 112 includes a processor that averages multiple values of power of the sinusoidal signal 134 over a predetermined time period to calculate an average power value, which is an example of the measured power 322. In the example, the processor multiplies a value of voltage measured by the V & I sensor 112 at a time with a value of current measured by the V & I sensor 112 at the time to determine one of the values of power. In this manner, for the predetermined time period, the values of power are determined. The current of the sinusoidal signal 134 is the coil current measurement signal 136 (FIG. 1).

The comparator 318 further receives DC bus power from the power sensor 120 (FIG. 1). As an example, the DC bus power is determined by a processor of the power sensor 120 as product of a DC bus voltage of the DC voltage signal 130 and a DC bus current of the DC voltage signal 130 (FIG. 1). In the example, the DC bus voltage and the DC bus current are detected by the power sensor 120. The comparator 318 also received DC set power from the user via the input device.

The comparator 318 compares the measured power 322 with the set power 320 to determine whether the measured power 322 is within a predetermined range from the set power 320. For example, the comparator 318 compares the measured power 322 with the set power 320 to determine that the measured power 322 is equal to the set power 320 to determine that the measured power 322 is within the predetermined range from the set power 320. In the example, the predetermined range is received by the comparator 318 from the user via the input device.

The comparator 318 compares the DC bus power with the DC set power to determine whether the DC bus power is within a predetermined range from the DC set power. For example, the comparator 318 compares the DC bus power with the DC set power to determine that the DC bus power is equal to the DC set power to determine that the DC bus power is within the predetermined range from the DC set power. In the example, the predetermined range is received by the comparator 318 from the user via the input device.

Upon determining that the measured power 322 is within the predetermined range from the set power 320 and the DC bus power is within the predetermined range from the DC set power, the comparator 318 provides a first indicator to the voltage controller 312. The first indicator indicates that the measured power 322 is within the predetermined range from the set power 320 and the DC bus power is within the predetermined range from the DC set power. On the other hand, upon determining that the measured power 322 is outside the predetermined range from the set power 320 or the DC bus power is outside the predetermined range from the DC set power or a combination thereof, the comparator 318 provides a second indicator to the voltage controller 312. The second indicator indicates that the measured power 322 is outside the predetermined range from the set power 320 or the DC bus power is outside the predetermined range from the DC set power or a combination thereof.

In response to receiving the first indicator, the voltage controller 312 does not modify a DC reference, such as the DC reference 224 or 226 (FIG. 2B). On the other end, in response to receiving the second indicator, the comparator 318 modifies the DC reference. For example, the comparator 318 increases or decreases the DC reference until the measured power 322 is within the predetermined range from the set power 320 and the DC bus power is within the predetermined range from the DC set power. The DC reference is modified to be within predetermined limits, such as between the upper peak value 231 and half of the upper peak value 231 or between the lower peak value 235 and half of the lower peak value 235 (FIG. 2B).

FIG. 3B is a diagram of an embodiment of a system 360 for modifying the voltage level of the DC voltage signal 130 to output the modified DC signal. The system 360 includes the processor 114. The processor 114 includes a logic circuit 362, a phase calculator 364, a comparator 366, and a pulse width modulator (PWM) 368. As an example, each of the logic circuit 362, the phase calculator 364, the comparator 366, and the PWM 368 is implemented as an integrated circuit. To illustrate, the logic circuit 362 is implemented as an integrated circuit and the phase calculator 364 is implemented as another integrated circuit. As another example, each of the logic circuit 362, the phase calculator 364, the comparator 366, and the PWM 368 is implemented as a computer software program that is executed by the processor 114 or a portion of a computer software program that is executed by the processor 114. For example, the logic circuit 362 is a portion of a computer software program and the phase calculator 364 is another portion of the computer software program.

The voltage controller 312 is coupled to the phase calculator 364, and the phase calculator 364 is coupled to the comparator 366. The logic circuit 362 is also coupled to the comparator 366. The comparator 366 is coupled to the PWM 368.

The phase calculator 364 receives a DC reference, such as the DC reference 224 or 226 (FIG. 2B), from the voltage controller 322 and determines the measured phase φmeasured based on the DC reference. For example, the phase calculator 364 calculates the measured phase φmeasured as a product of π and a difference between 1 and the DC reference 224. The phase calculator 364 provides the measured phase φmeasured to the comparator 366.

Moreover, the logic circuit 362 determines the optimal phase φoptimal based on the DC bus voltage and the DC bus current that are measured by the power sensor 120 (FIG. 1). For example, the processor 114 receives the DC bus voltage and the DC bus current from the power sensor 120. Further, in the example, the processor 114 calculates a product of a first term and a second term to generate the optimal phase φoptimal. In the example, the first term is a ratio of the measured power 322 and a product of the DC bus voltage and the DC bus current and the ratio is calculated by the processor 114. In the example, the second term is k, which is a constant received from the user via the input device. The logic circuit 362 provides the optimal phase φoptimal to the comparator 366.

The comparator 366 compares the measured phase φmeasured with the optimal phase φoptimal and provides a result of the comparison to the PWM 368. Based on the result, the PWM 368 controls, such as increases or decreases, the voltage level of the DC voltage signal 130 until the measured phase φmeasured is within a preset range from, such as equal to, the optimal phase φoptimal. For example, the comparator 366 outputs an indication to the PWM 368 that the measured phase φmeasured is not within the preset range from the optimal phase φoptimal. In the example, the PWM 368 increases or decreases the voltage level of the DC voltage signal 130 by applying pulse width modulation to the DC-DC converter 116 (FIG. 1) until an indication is received from the comparator 366 that the measured phase φmeasured is within the preset range from the optimal phase φoptimal. To illustrate, the PWM 368 outputs a digital pulsed signal having a duty cycle and the duty cycle determines the voltage level of the modified DC signal. In the illustration, with a decrease in the duty cycle, there is a decrease in the voltage level of the modified DC signal and with an increase in the duty cycle, there is an increase in the voltage level of the modified DC signal.

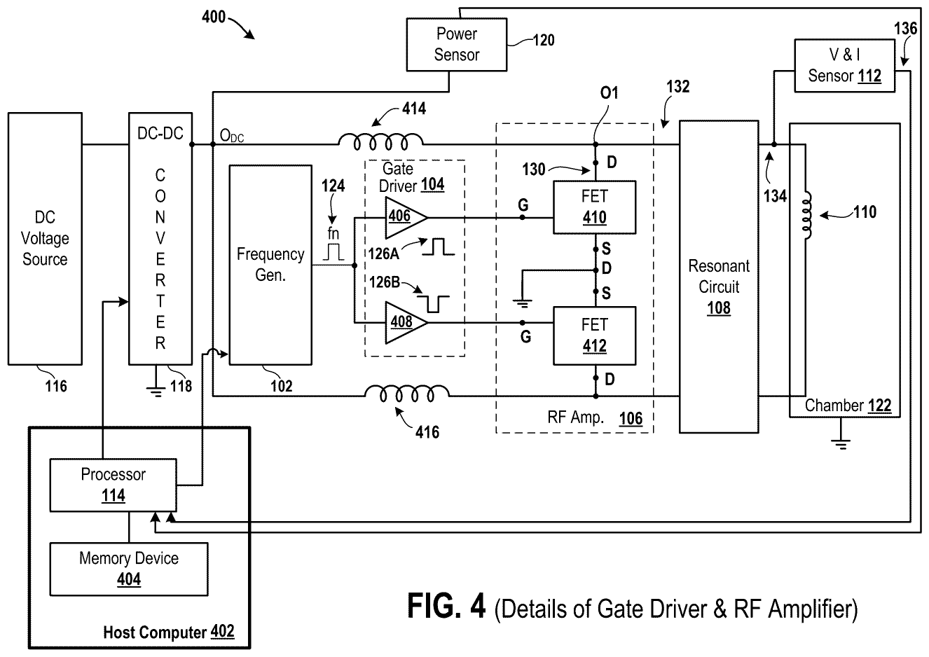

FIG. 4 is a diagram of an embodiment of a system 400 to illustrate details of the RF amplifier 106 and a manner in which the power sensor 120 is coupled to the output O_{DC} of the DC-to-DC converter 118. The system 400 includes a host computer 402, the frequency generator 102, the gate driver 104, the RF amplifier 106, the plasma chamber 122, the DC voltage source 116, the DC-to-DC converter 118, the power sensor 120, and the V & I sensor 112. The host computer 402 includes a processor 114 and a memory device 404. The processor 114 is coupled to the memory device 404. Examples of a memory device, as used herein, include a read-only memory (ROM) and a random access memory (RAM). To illustrate, the memory device is a flash memory or a redundant array of independent disks (RAID).

The gate driver 104 includes a gate 406, such as a buffer, and an inverter 408, such as a NOT gate. The RF amplifier 106 includes a field effect transistor (FET) 410 and another FET 412. Also, the system 400 includes an inductor 414 and another inductor 416.

The frequency generator 102 is coupled to the gate 406 and the inverter 408. An output of the gate 406 is coupled to a gate terminal (G) of the FET 410. A drain terminal (D) of the FET 410 is coupled to the output O1, which is coupled to the DC-to-DC converter 118 via the inductor 414. The output O1 is coupled to the resonant circuit 108. A source terminal(S) of the FET 410 is coupled to a reference potential, such as a ground potential. The inductor 414 is coupled to the DC-to-DC converter 118 and to the output O1. Also, a source terminal(S) of the FET 412 is coupled to the reference potential, and a drain terminal (D) of the FET 412 is coupled to the inductor 416 and to the resonant circuit 108. The inductor 416 is coupled to the output O_{DC} of the DC-to-DC converter 118 and to the resonant circuit 108. An output of the inverter 408 is coupled to a gate terminal (G) of the FET 412.

The digital pulsed signal 124 is provided from the frequency generator 102 to the gate 406 and to the inverter 408. The digital pulse signal 124 is sent to the gate 406, buffered at the gate 406, and passes through the gate 406 to output the gate driver signal 126A. The gate driver signal 126A is sent from the gate 406 to the gate terminal of the FET 410. The digital pulsed signal 124 is inverted by the inverter 408 the output an inverted digital pulsed signal, which is the gate driver signal 126B.

The gate driver signal 126B is reverse pulsed compared to the gate driver signal 126A. For example, when the gate driver signal 126A is in a logic high state, the gate driver signal 126B is in a low state and vice versa. The gate driver signal 126B is sent from the inverter 408 to the gate terminal of the FET 412.

The FET 410 is turned on during a time period in which the gate driver signal 126A is in the logic high state and is turned off during a time period in which the gate driver signal 126A is in the logic low state. Similarly, the FET 412 is turned on during a time period in which the gate driver signal 126B is in the logic high state and is turned off during a time period in which the gate driver signal 126B is in the logic low state. As such, because the gate driver signals 126A and 126B are reversely synchronized, during a time period in which the FET 410 is on, the FET 412 is off and during a time period in which the FET 410 is off, the FET 412 is on. As such, the FETs 410 and 412 are operated in reverse synchronization with each other.

Also, the DC voltage signal 130 is provided from the DC-to-DC converter 118 via the inductor 414 and the output O1 to the drain terminal of the FET 410. During the time period in which the FET 410 is on, a voltage of the DC voltage signal 130 generates a current that flows from the drain terminal of the FET 410 to the source terminal of the FET 410 to provide a voltage at the output O1. Also, during the time period in which the FET 412 is off, a voltage at the drain terminal of the FET 412 does not generate a current from the drain terminal of the FET 412 to the source terminal of the FET 412. Moreover, during the time period in which the FET 410 is off, the voltage of the DC voltage signal 130 does not generate the current from the drain terminal of the FET 410 to the source terminal of the FET 410. Also, during the time period in which the FET 412 is on, the voltage at the drain terminal of the FET 412 generates the current from the drain terminal of the FET 412 to the output O1 to generate a voltage of the output O1. In this manner, by operating the FETs 410 and 412 in reverse synchronization with each other, the voltage of the DC voltage signal 130 and the voltage at the drain terminal of the FET 412 generate the currents to generate the voltage at the output O1, and the voltage at the output O1 is of the amplification waveform 132.

The power sensor 120 measures the DC bus current and the DC bus voltage of the amplification waveform 132 generated at the output O_{DC}. Also, the V & I sensor 112 measures power of the sinusoidal waveform 134 to output the measured power 322 (FIG. 3B) to the processor 114. The processor 114 applies the method for determining the tuning frequency fn based on the DC bus current, the DC bus voltage, and the measured power 322.

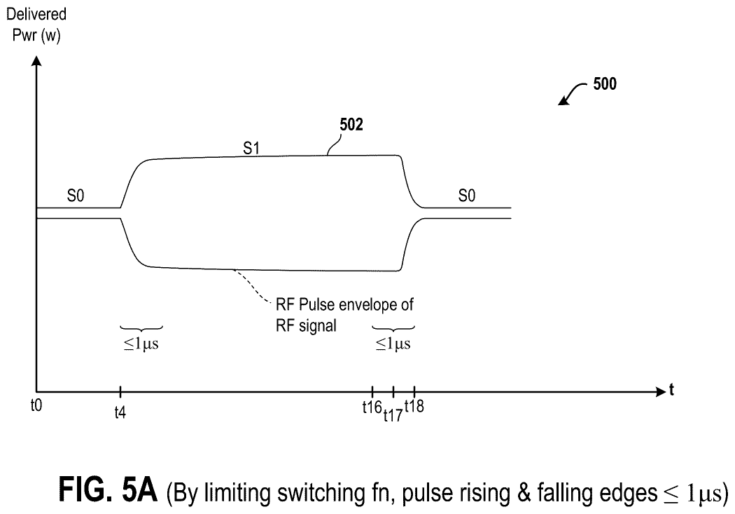

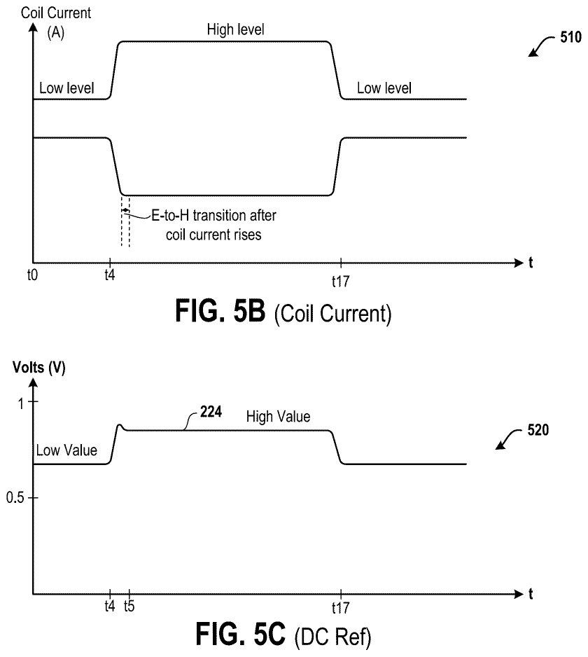

FIG. 5A is an embodiment of a graph 500 to illustrate a control of power that is delivered from the matchless plasma source, described herein, to achieve a predetermined rise time and a predetermined fall time. The predetermined rise time and the predetermined fall time are achieved when frequency generator 102 (FIG. 1) is controlled based on the tuning frequency fn. The graph 500 plots the delivered power from the matchless plasma source on a y-axis and the time t on an x-axis. The graph 500 plots an envelope 502 of the delivered power of the modified sinusoidal waveform output from the resonant circuit 108 (FIG. 1) to illustrate the delivered power that is output from the matchless plasma source.

The envelope 502 starts transitioning from a low state S0 to a high state S1 at the time t4 and starts transitioning back from the high state S1 to the low state S0 at the time t16. As illustrated in the graph 500, a time period of transition from the low state S0 to the high state S1 is less than the predetermined rise time and a time period of transition from the high state S1 to the low state S0 is less than the predetermined fall time. For example, the time period of transition from the high state to the low state is 0.75 microsecond (μs) or 1 μs and the time period of transition from the high state to the low state is 0.75 μs or 1 μs.

FIG. 5B is an embodiment of a graph 510 to illustrate occurrences of smooth transitions of plasma formed within the plasma chamber 122 (FIG. 1) from an electric mode (E) to a magnetic mode (H) and smooth transitions of the plasma from the H mode to the E mode. The graph 510 plots an envelope of an RF coil current passing through the RF coil 110 (FIG. 1) versus the time t. The RF coil current passing through the RF coil 110 is illustrated by the coil current measurement signal 202 (FIG. 2A). The envelope of the RF coil current starts transitioning from a low level to a high level at the time t4 and from the high level to the low level at the time t17. The transition of plasma from the E mode to the H mode occurs immediately after the envelope of the RF coil current transitions from the low level to the high level.

FIG. 5C is an embodiment of a graph 224 to illustrate a change in the DC reference 224 with a change in a level of the coil current passing through the RF coil 110 (FIG. 1). The graph 520 plots voltage of the DC reference 224 on a y-axis and the time t on an x-axis. At the time t4 at which the coil current passing through the RF coil 110 starts transitioning from the low level to the high level, the DC reference 224 starts transitioning from a low value to a high value. Also, at the time t17 at which the coil current passing through the RF coil 110 starts transitioning from the high level to the low level, the DC reference 224 starts transitioning from the high value to the low value.

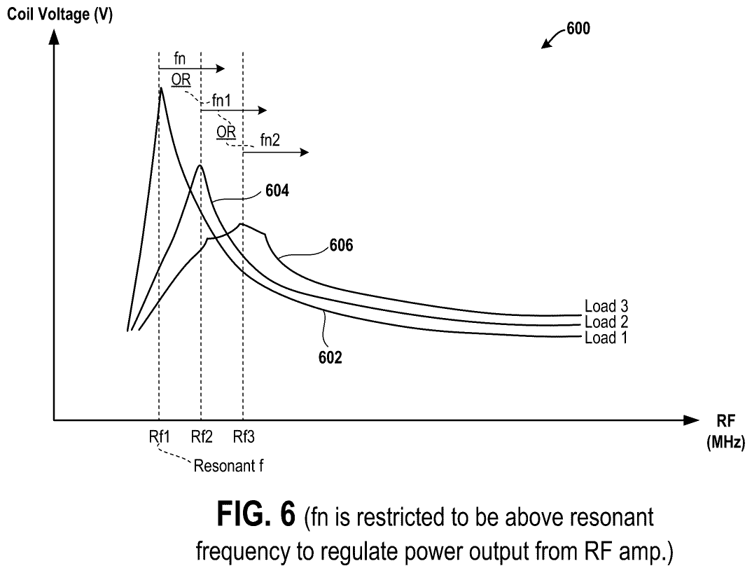

FIG. 6 is an embodiment of a graph 600 to illustrate that for different loads, the frequency generator 102 (FIG. 1) is operated at different tuning frequencies to achieve the zero voltage switching. Also, each of the different tuning frequencies are above a respective resonant frequency for a respective one of the loads. The graph 600 plots a voltage at the input I1 of the RF coil 110 (FIG. 1) versus a frequency of a sinusoidal signal, such as the modified sinusoidal signal, at the input I1 of the RF coil 110.

An example of a load is impedance of plasma formed within the plasma chamber 122 (FIG. 1). For example, a load 1 represents that the plasma is formed using a gas recipe, such as a first combination of two or more of the process gases, a load 2 represents of the plasma is formed using another gas recipe, such as a second combination of two or more of the process gases, and a load 3 represents of the plasma is formed using yet another gas recipe, such as a third combination of two or more of the process gases. As another example, the load 1 represents the plasma chamber 122, the load 2 represents a different plasma chamber, and the load 3 represents yet another different plasma chamber.

The graph 600 includes a plot 602 generated when the modified sinusoidal signal is applied to the load 1, a plot 604 when another modified sinusoidal signal is applied to the load 2, and a plot 606 when yet another modified sinusoidal signal is applied to the load 3. Each plot 602, 606, and 606 has a corresponding resonant frequency (f). For example, the plot 602 has a resonant frequency Rf1, the plot 604 has a resonant frequency Rf2, and the plot 505 has a resonant frequency RF3.

When the modified sinusoidal signal is applied to the load 1, the frequency generator 102 is controlled by the processor 114 to operate at the tuning frequency fn that is greater than the resonant frequency Rf1. Similarly, when the other modified sinusoidal signal is applied to the load 2, the frequency generator 102 is controlled by the processor 114 to operate at a tuning frequency fn1 that is greater than the resonant frequency Rf2. Also, when the yet another modified sinusoidal signal is applied to the load 3, the frequency generator 102 is controlled by the processor 114 to operate at a tuning frequency fn2 that is greater than the resonant frequency Rf3. By controlling the frequency generator 102 to operate at a tuning frequency greater than a respective resonance frequency for a load, power that is output from the RF amplifier 106 (FIG. 1) is regulated or controlled.

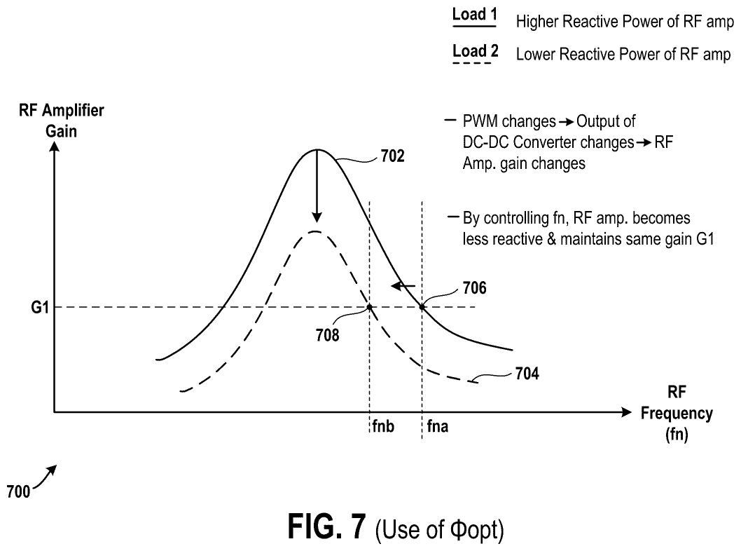

FIG. 7 is an embodiment of a graph 700 to illustrate that by controlling the tuning frequency fn, the RF amplifier 106 (FIG. 1) becomes less reactive and provides the same amount of gain of RF power. The graph 700 plots an amount of gain of RF power output from the RF amplifier 106 on a y-axis and the tuning frequency fn on an x-axis.

The graph 700 includes a plot 702, which is generated when the RF amplifier 106 has a higher reactive power and a plot 704, which is generated when the RF amplifier has a lower reactive power. With a change in the duty cycle output by the PWM 368 (FIG. 3B), the DC voltage signal 130 changes to the modified DC signal to change the amount of gain at the output O1 (FIG. 1) of the RF amplifier 106. Moreover, by controlling the tuning frequency fn, such as modifying the tuning frequency fn, from a value fna to a value fnb, the RF amplifier 106 becomes less reactive, as illustrated by a movement from a point 706 on the plot 702 to a point 708 on the plot 704, and the same amount of gain G1 is output by the RF amplifier 106.

Embodiments described herein may be practiced with various computer system configurations including hand-held hardware units, microprocessor systems, microprocessor-based or programmable consumer electronics, minicomputers, mainframe computers and the like. The embodiments can also be practiced in distributed computing environments where tasks are performed by remote processing hardware units that are linked through a network.

In some embodiments, a controller, described herein, is a part of a system, which may be part of the above-described examples. Such systems include semiconductor processing equipment, including a processing tool or tools, chamber or chambers, a platform or platforms for processing, and/or specific processing components (a wafer pedestal, a gas flow system, etc.). These systems are integrated with electronics for controlling their operation before, during, and after processing of a semiconductor wafer or substrate. The electronics is referred to as the “controller,” which may control various components or subparts of the system or systems. The controller, depending on the processing requirements and/or the type of system, is programmed to control any of the processes disclosed herein, including the delivery of process gases, temperature settings (e.g., heating and/or cooling), pressure settings, vacuum settings, power settings, RF generator settings, RF matching circuit settings, frequency settings, flow rate settings, fluid delivery settings, positional and operation settings, wafer transfers into and out of a tool and other transfer tools and/or load locks coupled to or interfaced with a system.

Broadly speaking, in a variety of embodiments, the controller is defined as electronics having various integrated circuits, logic, memory, and/or software that receive instructions, issue instructions, control operation, enable cleaning operations, enable endpoint measurements, and the like. The integrated circuits include chips in the form of firmware that store program instructions, digital signal processors (DSPs), chips defined as ASICs, PLDs, and/or one or more microprocessors, or microcontrollers that execute program instructions (e.g., software). The program instructions are instructions communicated to the controller in the form of various individual settings (or program files), defining the parameters, the factors, the variables, etc., for carrying out a particular process on or for a semiconductor wafer or to a system. The program instructions are, in some embodiments, a part of a recipe defined by process engineers to accomplish one or more processing steps during the fabrication of one or more layers, materials, metals, oxides, silicon, silicon dioxide, surfaces, circuits, and/or dies of a wafer.

The controller, in some embodiments, is a part of or coupled to a computer that is integrated with, coupled to the system, otherwise networked to the system, or a combination thereof. For example, the controller is in a “cloud” or all or a part of a fab host computer, which allows for remote access of the wafer processing. The computer enables remote access to the system to monitor current progress of fabrication operations, examines a history of past fabrication operations, examines trends or performance metrics from a plurality of fabrication operations, to change parameters of current processing, to set processing steps to follow a current processing, or to start a new process.

In some embodiments, a remote computer (e.g. a server) provides process recipes to a system over a network, which includes a local network or the Internet. The remote computer includes a user interface that enables entry or programming of parameters and/or settings, which are then communicated to the system from the remote computer. In some examples, the controller receives instructions in the form of data, which specify the parameters, factors, and/or variables for each of the processing steps to be performed during one or more operations. It should be understood that the parameters, factors, and/or variables are specific to the type of process to be performed and the type of tool that the controller is configured to interface with or control. Thus as described above, the controller is distributed, such as by including one or more discrete controllers that are networked together and working towards a common purpose, such as the processes and controls described herein. An example of a distributed controller for such purposes includes one or more integrated circuits on a chamber in communication with one or more integrated circuits located remotely (such as at the platform level or as part of a remote computer) that combine to control a process on the chamber.

Without limitation, in various embodiments, example systems to which the methods are applied include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, and any other semiconductor processing systems that is associated or used in the fabrication and/or manufacturing of semiconductor wafers.

It is further noted that in some embodiments, the above-described operations apply to several types of plasma chambers, e.g., a plasma chamber including an inductively coupled plasma (ICP) reactor, a capacitively coupled plasma (CCP) chamber, a transformer coupled plasma chamber, conductor tools, dielectric tools, a plasma chamber including an electron cyclotron resonance (ECR) reactor, etc. For example, one or more RF generators are coupled to an inductor within the ICP reactor. Examples of a shape of the inductor include a solenoid, a dome-shaped coil, a flat-shaped coil, etc.

As noted above, depending on the process step or steps to be performed by the tool, the host computer communicates with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

With the above embodiments in mind, it should be understood that some of the embodiments employ various computer-implemented operations involving data stored in computer systems. These operations are those physically manipulating physical quantities. Any of the operations described herein that form part of the embodiments are useful machine operations.

Some of the embodiments also relate to a hardware unit or an apparatus for performing these operations. The apparatus is specially constructed for a special purpose computer. When defined as a special purpose computer, the computer performs other processing, program execution or routines that are not part of the special purpose, while still being capable of operating for the special purpose.

In some embodiments, the operations may be processed by a computer selectively activated or configured by one or more computer programs stored in a computer memory, cache, or obtained over the computer network. When data is obtained over the computer network, the data may be processed by other computers on the computer network, e.g., a cloud of computing resources.

One or more embodiments can also be fabricated as computer-readable code on a non-transitory computer-readable medium. The non-transitory computer-readable medium is any data storage hardware unit, e.g., a memory device, etc., that stores data, which is thereafter be read by a computer system. Examples of the non-transitory computer-readable medium include hard drives, network attached storage (NAS), ROM, RAM, compact disc-ROMs (CD-ROMs), CD-recordables (CD-Rs), CD-rewritables (CD-RWs), magnetic tapes and other optical and non-optical data storage hardware units. In some embodiments, the non-transitory computer-readable medium includes a computer-readable tangible medium distributed over a network-coupled computer system so that the computer-readable code is stored and executed in a distributed fashion.

Although the method operations above were described in a specific order, it should be understood that in various embodiments, other housekeeping operations are performed in between operations, or the method operations are adjusted so that they occur at slightly different times, or are distributed in a system which allows the occurrence of the method operations at various intervals, or are performed in a different order than that described above.

It should further be noted that in an embodiment, one or more features from any embodiment described above are combined with one or more features of any other embodiment without departing from a scope described in various embodiments described in the present disclosure.

Although the foregoing embodiments have been described in some detail for purposes of clarity of understanding, it will be apparent that certain changes and modifications can be practiced within the scope of appended claims. Accordingly, the present embodiments are to be considered as illustrative and not restrictive, and the embodiments are not to be limited to the details given herein.

1. A method for tuning a frequency of a radio frequency (RF) amplifier, comprising:
receiving a coil current measurement signal, wherein the coil current measurement signal is measured at an input of an RF coil of a plasma chamber;
generating a first sawtooth signal based on the coil current measurement signal;
applying a plurality of direct current (DC) references to the first sawtooth signal to determine a tuning frequency; and
controlling a frequency generator of a matchless plasma source according to the tuning frequency, wherein the tuning frequency is the frequency of the RF amplifier.

2. The method of claim 1, wherein said generating the first sawtooth signal based on the coil current measurement signal comprises:
generating a square pulse signal across the coil current measurement signal;
integrating the square pulse signal to generate a second sawtooth signal; and
normalizing the second sawtooth signal to output a normalized sawtooth signal, wherein the first sawtooth signal is the normalized sawtooth signal.

3. The method of claim 2, further comprising:
identifying one or more zero crossings of the coil current measurement signal, wherein the square pulse signal is integrated based on the zero crossings.

4. The method of claim 1, wherein the first sawtooth signal has a peak value, wherein one of the plurality of DC references is limited between an upper predetermined value and a lower predetermined value, wherein the upper predetermined value is determined based on the peak value, and the lower predetermined value is determined based on the upper predetermined value.

5. The method of claim 4, wherein the upper predetermined value is equal to the peak value.

6. The method of claim 4, wherein the lower predetermined value is less than the peak value by a predetermined increment.

7. The method of claim 1, further comprising:
determining a measured phase based on the one of the plurality of DC references;
determining an optimal phase based on power measured at the input of the RF coil, a DC bus voltage measured at an output a DC-to-DC converter, and a DC bus current measured at the output of the DC-to-DC converter;
comparing the measured phase with the optimal phase to determine a duty cycle; and
applying a pulse width based on the duty cycle to the DC-DC converter.

8. The method of claim 1, wherein the plurality of DC references include a first DC reference and a second DC reference, wherein said applying the plurality of DC references to the first sawtooth signal includes:
determining a first time at which the first sawtooth signal transitions from being less the first DC reference to being greater than the first DC reference;
determining a second time at which the first sawtooth signal transitions from being greater than the second DC reference to being less than the second DC reference, wherein the second time occurs after the first time,
wherein the tuning frequency is determined based on the first and second times.

9. The method of claim 1, wherein the matchless plasma source excludes a match.

10. A controller for tuning a frequency of a radio frequency (RF) amplifier, comprising:
a processor configured to:
receive a coil current measurement signal, wherein the coil current measurement signal is measured at an input of an RF coil of a plasma chamber;
generate a first sawtooth signal based on the coil current measurement signal;
apply a plurality of direct current (DC) references to the first sawtooth signal to determine a tuning frequency; and
control a frequency generator of a matchless plasma source according to the tuning frequency, wherein the tuning frequency is the frequency of the RF amplifier; and
a memory device coupled to the processor.

11. The controller of claim 10, wherein to generate the first sawtooth signal, the processor is configured to:
generate a square pulse signal across the coil current measurement signal;
integrate the square pulse signal to generate a second sawtooth signal; and
normalize the second sawtooth signal to output a normalized sawtooth signal, wherein the first sawtooth signal is the normalized sawtooth signal.

12. The controller of claim 11, wherein the processor is configured to:
identify one or more zero crossings of the coil current measurement signal, wherein the square pulse signal is integrated based on the zero crossings.

13. The controller of claim 10, wherein the first sawtooth signal has a peak value, wherein one of the plurality of DC references is limited between an upper predetermined value and a lower predetermined value, wherein the upper predetermined value is determined based on the peak value, and the lower predetermined value is determined based on the upper predetermined value.

14. The controller of claim 13, wherein the upper predetermined value is equal to the peak value.

15. The controller of claim 13, wherein the lower predetermined value is less than the peak value by a predetermined increment.

16. The controller of claim 10, wherein the processor is configured to:
determine a measured phase based on one of the plurality of DC references;
determine an optimal phase based on power measured at the input of the RF coil, a DC bus voltage measured at an output a DC-to-DC converter, and a DC bus current measured at the output of the DC-to-DC converter;
compare the measured phase with the optimal phase to determine a duty cycle; and
apply a pulse width based on the duty cycle to the DC-DC converter.

17. The controller of claim 10, wherein the plurality of DC references include a first DC reference and a second DC reference, wherein to apply the plurality of DC references to the first sawtooth signal, the processor is configured to:
determine a first time at which the first sawtooth signal transitions from being less the first DC reference to being greater than the first DC reference;
determine a second time at which the first sawtooth signal transitions from being greater than the second DC reference to being less than the second DC reference, wherein the second time occurs after the first time,
wherein the tuning frequency is determined based on the first and second times.

18. The controller of claim 10, wherein the matchless plasma source excludes a match.

19. A system comprising:
a matchless plasma source including:
a frequency generator configured to generate a digital pulsed signal;
a gate driver coupled to the frequency generator, wherein the gate driver is configured to receive the digital pulsed signal to output a plurality of gate driver signals;
a radio frequency (RF) amplifier coupled to the gate driver and having an output, wherein the RF amplifier is configured to receive the plurality of gate driver signals to provide an amplification waveform at the output of the RF amplifier;
a resonant circuit coupled to the RF amplifier, wherein the resonant circuit is configured to receive the amplification waveform to output a sinusoidal signal; and
a plasma chamber having an RF coil, wherein the RF coil has an input coupled to the resonant circuit to receive the sinusoidal signal; and
a controller coupled to the matchless plasma source, wherein the controller is configured to:
receive a coil current measurement signal, wherein the coil current measurement signal is measured at the input of the RF coil;
generate a first sawtooth signal based the coil current measurement signal;
apply a plurality of direct current (DC) references to the first sawtooth signal to determine a tuning frequency; and
control the frequency generator according to the tuning frequency.

20. The system of claim 19, wherein to generate the first sawtooth signal, the processor is configured to:
generate a square pulse signal across the coil current measurement signal;
integrate the square pulse signal to generate a second sawtooth signal; and
normalize the second sawtooth signal to output a normalized sawtooth signal, wherein the first sawtooth signal is the normalized sawtooth signal.
